(19) United States
(12) Patent Application Publication
(10) Pub. No.: US 2024/0206350 A1
(43) Pub. Date: Jun. 20, 2024

(54) QUANTUM DEVICE

(71) Applicant: NEC Corporation, Tokyo (JP)

(72) Inventors: Tomohiro Yamaji, Tokyo (JP); Yohei Kawakami, Tokyo (JP)

(73) Assignee: NEC Corporation, Tokyo (JP)

(21) Appl. No.: 18/544,605

(22) Filed: Dec. 19, 2023

(30) Foreign Application Priority Data
Dec. 20, 2022 (JP) 2022-203171

(51) Int. Cl. H10N 60/80; H10N 60/12; H10N 60/82; H10N 69/00

(52) U.S. Cl. CPC H10N 60/805; H10N 60/12; H10N 60/82; H10N 69/00

(57) ABSTRACT

A quantum device includes on a wiring pattern of first lines and second lines coupled capacitively and inductively to qubits, respectively, and third lines and fourth lines coupled capacitively and inductively to couplers, respectively. The wiring pattern includes a first pattern of adjacent three lines in which one of the second line and the fourth line is disposed between two lines selected from the first lines and the third lines, and/or a second pattern of adjacent three lines in which two lines selected from the second lines and the fourth lines are disposed on both sides of one of the first line and the third line.

### FIELD

### Cross Reference to Related Applications

This application is based upon and claims the benefit of the priority of Japanese patent application No. 2022-203171, filed on Dec. 20, 2022, the disclosure of which is incorporated herein in its entirety by reference thereto.

The present invention relates to a quantum device provided with a superconducting circuit.

### BACKGROUND

A quantum bit (qubit) including a superconducting quantum circuit, is typically configured as a planar circuit formed by e.g., deposition of a superconducting material on a high resistance semiconductor substrate, and a non-linear inductor such as a Josephson junction and a superconducting quantum interference device (SQUID) including multiple Josephson junctions.

A coupling of qubits (such as two-body and four-body coupling), an input line for initializing a quantum state of each qubit, an output line for reading out a quantum state, and a pump line for adjusting a resonance frequency of the qubit with a SQUID are provided to perform quantum computation by combining multiple qubits. A scheme in which an input line and an output line are integrated as an input/output (IO) line by disposing a qubit with reflection-type arrangement, and a scheme in which multiple readout resonators are provided for multiple qubits, respectively and multiplexed readout is performed by connecting multiple readout resonators to a single output line (readout line) are widely used (reference may be made to Non-Patent Literatures (NPL) 2 and 3).

In a quantum annealing computer, a network in which Josephson Parametric Oscillators (JPOs) are coupled with each other by four-body interaction is disclosed in NPL 1. In NPL 1, a JPO corresponds to (is denoted as) JPA (Josephson Parametric Amplifier).

In the JPO, it is possible to adjust a resonance frequency by supplying a direct current to a pump line coupled via a mutual inductance to the SQUID of the JPO. By applying a pump wave (AC (Alternating current)) to the pump line, an output signal wave (half frequency of the pump wave) is output from an input/output line due to oscillation. A relative phase of the output signal wave depends on an oscillation state of the JPO. The oscillation state can be controlled by an input signal wave.

JPOs may be arranged in a pyramidal square lattice pattern as illustrated in FIG. 15B. A product of two logical bits is redundantly embedded as a physical bit. This allows to represent an Ising problem of all-to-all connected logical bits by coupling of physical bits loosely coupled. FIG. 15A and FIG. 15B are diagrams based on FIG. 4b and FIG. 4c (Physical realization of the LHZ scheme) of NPL 1. In the LHZ (derived from Lechner, Hauke, Zoller) scheme, a problem that an optimization problem requires control of long-range interaction between many Ising spins is solved by mapping the Ising problem on a graph with local interactions. A pair of N logical spins is mapped to M=N (N-1)/2 physical spins. Logical spin pairs Jᵢ and Jⱼ (i≠j=1, . . . , N) are mapped to physical spins J′_{i,j} (J′_{i,j}=Jᵢ×Jⱼ) and J′_{i,j} are encoded in J′ₖ (for example, J′_{1, 5} is encoded in J′₁, J′_{2, 5} is encoded in J′₃, . . . ). In FIG. 15A, a graph structure of a fully-connected Ising model with N=5 logical spins is illustrated. FIG. 15B is a diagram in which the graph structure of the fully-connected Ising model with N=5 logical spins illustrated in FIG. 15A is mapped to M=10 physical spins. A circle O represents a coupler including Josephson junctions as non-linear elements (non-linear inductors) and four rectangles coupled thereto represent qubits (JPO). These configures a basic unit (“Plaquette”). In FIG. 15B, three physical bits below the lowest side physical bits are fixed bits (spin-fixed).
[NPL 1] S. Puri, et al., “Quantum annealing with all-to-all connected nonlinear oscillators,” Nature Communications 8(1), June 2017.
[NPL 2] Evan Jeffrey, et al., “Fast Scalable State Measurement with Superconducting Qubits,” Phys. Rev. Lett. 112, 190504, 15 May 2014.
[NPL 3] Johannes Heinsoo et. al. “Rapid High-fidelity Multiplexed Readout of Superconducting Qubits,” Phys. Rev. Applied 10, 034040.

### SUMMARY

It is an object of the present disclosure to provide a quantum device with wiring enabled to improve signal quality for a network with qubits and couplers.

According to one aspect of the disclosure, there is provided a quantum device including on a wiring layer of a substrate:
a plurality of qubits; a plurality of couplers, four of the plurality of qubits being connected to each of the plurality of couplers; a first line capacitively coupled to each of the plurality of qubits; a second line inductively coupled to each of the plurality of qubits; a third line capacitively coupled to each of the plurality of couplers; and a fourth line inductively coupled to each of the plurality of couplers.
   The first line is one of a plurality of first lines, the second line is one of a plurality of second lines, the third line is one of a plurality of third lines, the fourth line is one of a plurality of fourth lines.
   A wiring pattern includes at least one of a first pattern and a second pattern, as a wiring pattern including the plurality of first lines and the plurality of second lines coupled to the plurality of qubits, respectively, and the plurality of third lines and the plurality of fourth lines, coupled to the plurality of couplers, respectively.
   The first pattern includes a pattern of adjacent three lines in which one of the second line and the fourth line is disposed between two lines selected from among the plurality of first lines and the plurality of third lines without distinguishing between the first line and the third line. The second pattern includes a pattern of adjacent three lines in which two lines selected from among the plurality of second line and the plurality of fourth line are disposed on both sides of one of the first line and the third line.

According to the present disclosure, a quantum device provided with wiring that enables to improve signal quality, etc., for a network of qubits having a plurality of couplers can be provided.

### BRIEF DESCRIPTION OF DRAWINGS

FIG. 1 is a diagram illustrating one of example embodiments.

FIGS. 2A and 2B are diagram illustrating one of examples illustrated in FIG. 1.

FIGS. 2C and 2D are diagram illustrating one of examples illustrated in FIG. 1.

FIG. 3A is a diagram illustrating one of examples illustrated in FIG. 1.

FIG. 3B is a diagram illustrating one of examples illustrated in FIG. 1.

FIG. 4 is a diagram illustrating one of examples of connection with a JPO illustrated in FIG. 1.

FIG. 5 is a diagram illustrating one of examples of a connection with a coupler illustrated in FIG. 1

FIG. 6 is a diagram illustrating one of examples.

FIG. 7 is a diagram illustrating one of examples of a configuration illustrated in FIG. 6 extended in a lateral direction.

FIG. 8A is a diagram illustrating one of examples of each configuration of quantum chips illustrated in FIG. 7.

FIG. 8B is a diagram illustrating one of examples of each circuit pattern of quantum chips illustrated in FIG. 8A.

FIG. 9 is a diagram illustrating one of examples of configuration illustrated in FIG. 6 extended in a longitudinal direction.

FIG. 10A is a diagram illustrating one of examples of configuration illustrated in FIG. 6 extended in a longitudinal direction.

FIG. 10B is a diagram illustrating one of examples of configuration illustrated in FIG. 6 extended in a longitudinal direction.

FIG. 11 is a schematic cross-sectional view illustrating chips illustrated in FIG. 10A and FIG. 10B.

FIG. 12 is a diagram illustrating one of example embodiments.

FIG. 13 is a diagram illustrating one of example embodiments.

FIG. 14 is a diagram illustrating one of example embodiments.

FIG. 15A is a diagram cited from NPL 1.

FIG. 15B is a diagram cited from NPL 1.

### EXAMPLE EMBODIMENTS

In the following description of examples, reference is made to the accompanying drawings which form a part hereof, and in which it is shown by way of illustration specific examples that can be practiced. It is to be understood that other examples can be used and structural changes can be made without departing from the scope of the disclosed examples. It is noted that in the disclosure, the expression “at least one of A and B” means A, B, or (A and B). The term expressed as “−(s)” includes both singular and/or plural form. A four-body interaction coupler has an effect of excluding such an arrangement with inverted conversion thereof to logical bits not enabled, which can be caused by redundancy, by configuring coupled four bits as an even parity arrangement (even number of −1's). Although this scheme is loosely coupled, it is necessary to arrange wiring, for each qubit, an input/output line and a pump line. For each qubit, a signal wave close to a resonance frequency of the qubit is applied via the input/output line to the qubit and via the pump line, DC (direct current) and/or a wave twice the frequency of the signal is applied to the qubit. In a case that a four-body interaction coupler is configured with a resonator that includes a SQUID (superconducting quantum interference device), a coupler also requires two lines of an input/output line and a control line (with only DC applied thereto). When implementing the four-body interaction coupler on an integrated circuit, wiring will become an issue. NPL1 proposed only a theoretical proposal, and there is no description of concrete specific configuration regarding wiring of a JPO network with a plurality of couplers. The above issue is one of examples, but the present disclosure is not limited to the above and can provide a quantum device with an improved signal quality in various situations.

A first line and a second line may be an input/output line and a pump line, respectively, connected to a qubit described below. A third line and a fourth line may be an input/output line and a control line, respectively, connected to a coupler described below.

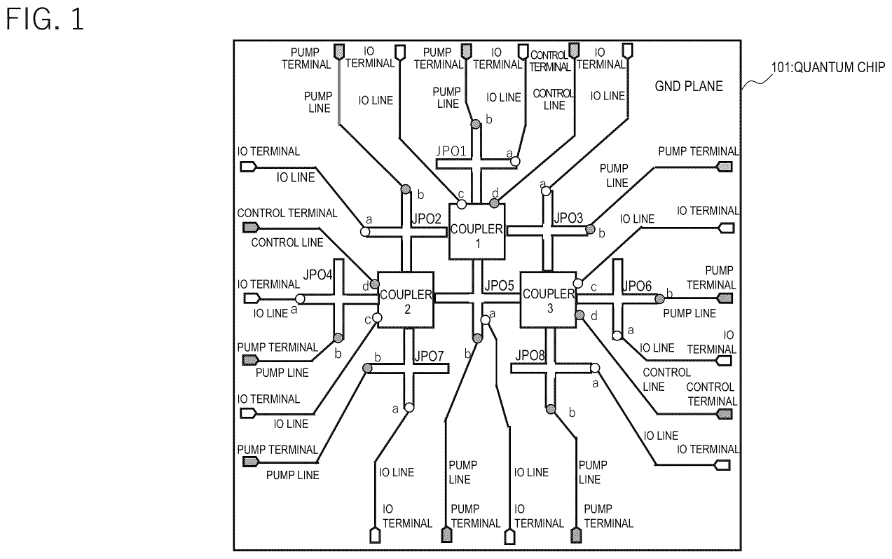

The following describes several examples of the present disclosure. FIG. 1 is a diagram illustrating one of examples. FIG. 1 schematically illustrates a plan view of a circuit pattern of a wiring layer on a substrate surface of a quantum chip 101, viewed from above. Referring to FIG. 1, the wiring layer of the quantum chip 101 is provided with three couplers (coupler 1, coupler 2 and coupler 3), eight qubits (JPO 1 to JPO 8), (first) input/output (IO) lines, pump lines, (second) input/output (IO) lines, control lines, input/output (IO) terminals, pump terminals, and control terminals. The three couplers each couple neighboring four qubits by a four-body interaction. Via the (first) IO line, a signal wave is supplied and output to and from each qubit. Via the pump line, a pump wave is transmitted to each qubit. Via the (second) IO line, a signal wave is supplied and output to and from each coupler. Via the control line, a DC signal (control signal) is supplied to each coupler. The IO terminal is used for reception and output of the signal wave from and to an external equipment (not shown). The pump terminal is used for receiving the pump wave. The control terminal is used for reception of the DC signal (control signal).

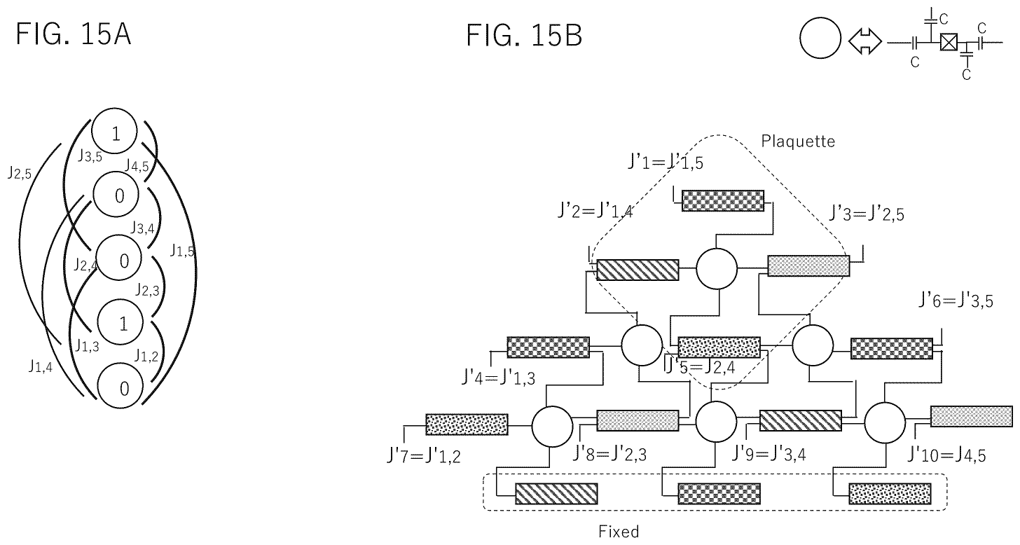

In the example embodiment, each qubit is configured by JPO. In the following description and drawings, qubit is referred to as JPO. A plurality of JPOs and a plurality of couplers are arranged in a pyramidal square lattice. A coupler capacitively coupled to four nearest-neighbor JPOs. The coupler and the four nearest-neighbor JPOs form a unit structure (basic unit). In FIG. 1, the quantum chip 101 is provided with a unit structure 1 (JPO 2, JPO 1, JPO 3, JPO 5, and coupler 1), a unit structure 2 (JPO 4, JPO 2, JPO 5, JPO 7, and coupler 2), and a unit structure 3 (JPO 5, JPO 3, JPO 6, JPO 8, and coupler 3). JPO2 is shared by the unit structures 1 and 2, JPO3 is shared by the unit structures 1 and 3, and JPO5 is shared by the unit structures 1, 2, and 3. A circuit pattern in FIG. 1 corresponds to a structure in which a fully (all-to-all) connected Ising model with N=4 logical spins are mapped to M=N*(N-1)/2=6 physical spins (in FIGS. 15A and 15B, N=5, M=10). Two physical bits (JPO 7 and JPO 8) below the lowest side physical bits are fixed bits (spin-fixed). In the drawings and a following description, the input/output lines and the input/output terminals are termed as IO lines and IO terminals, respectively.

In FIG. 1. each JPO, which is made of a superconducting material, has, as a planar shape, for example, a cross-shaped electrode structure with four arms of equal length crossing each other at a right angle in the center. In each JPO and each coupler in FIG. 1, capacitively coupled ports are illustrated as a white circle and inductively coupled (coupled with mutual inductance) ports are illustrated as a gray circle. The IO terminals wired respectively to the capacitively coupled ports of each JPO and each coupler are illustrated as a white terminal, and terminals (pump terminal/control terminal) wired respectively to the inductively coupled ports of each JPO and each coupler are illustrated as a gray terminal. That is, the capacitively coupled port (IO port) of each JPO which is capacitively coupled via a coupling capacitor (not shown) with an arm of the cross-shaped electrode of the JPO, is represented by a white circle each marked with a reference sign “a”. The inductively coupled port (pump port) of each JPO which is inductively coupled via a mutual inductance (magnetically) to the SQUID resonator (not shown) connected to the arm of the cross-shaped electrode of the JPO is represented by a gray circle each marked with reference sign “b”. In the coupler, the capacitively coupled port (IO port) which is capacitively coupled via a coupling capacitor (not shown) to the IO line is represented by a white circle each marked with a reference sign “c”, and the inductively coupled port (control port) which is inductively coupled with the control line is represented by a gray circle each marked with reference sign “d”. In an example illustrated in FIG. 1, the IO terminals, which are wired respectively to the capacitively coupled ports of JPOs and couplers, and terminals (pump terminals/control terminals), which are wired respectively to the inductively coupled ports of JPOs and couplers are arranged alternately.

For example, at an outer edge portion (chip periphery) of the wiring layer of the quantum chip 101 in FIG. 1,
a pump terminal connected to a second end of a pump line with a first end thereof connected to the inductively coupled port b of the JPO 2;
an IO terminal connected to a second end of an IO line with a first end thereof connected to a capacitively coupled port c of the coupler 1;
a pump terminal, which is connected to a second end of a pump line with a first end thereof connected to an inductively coupled port b of the JPO 1;
an IO terminal connected to a second end of an IO line with a first end thereof connected to a capacitively coupled port a of the JPO 1;
a control terminal connected to a second end of a control line with a first end thereof connected to an inductively coupled port d of the coupler 1; and
an IO terminal connected to a second end of an IO line with one end connected to a capacitively coupled port a of the JPO 3, are lined up in a row at an upper side of the drawing of the quantum chip 101. That is, a pump terminal/control terminal (pump line/control line) and an IO terminal (IO line) are arranged alternately (by turns). For example, a pump terminal (pump line) is disposed between two IO terminals (IO lines), and a control terminal is disposed between two IO terminals (IO lines). This configuration reduces an effect of crosstalk between lines on which the same type of signals (e.g., signal waves) are transmitted.

From another point of view, a pump line of the JPO 1 is disposed between an IO line connected to the coupler 1 and an IO line connected to the JPO 1, which enables to reduce crosstalk between the IO lines. A control line connected to the coupler 1 is disposed between an IO line connected to the JPO 1 and an IO line connected to the JPO 3, which enables to reduce crosstalk between the IO lines. From yet another point of view, a pump line connected to the JPO 1 and a control line connected to the coupler 1 are disposed on both sides of an IO line connected to the JPO1, respectively. This enables to reduce an effect of crosstalk that the IO line connected to the JPO1 receives from other IO lines.

At an outer edge portion (chip periphery) of the wiring layer of the quantum chip 101,
an IO terminal connected to a second end of an IO line with a first end thereof connected to a capacitively coupled port a of the JPO 7;
a pump terminal connected to a second end of a pump line with a first end thereof connected to an inductively coupled port b of the JPO 5,
an IO terminal connected to a second end of an IO line with a first end thereof connected to a capacitively coupled port a of the JPO 5; and
a pump terminal connected to a second end of a pump line with a first end thereof connected to an inductively coupled port b of the JPO 8, are lined up in a row. The IO terminals (IO lines) and the pump terminals (pump lines) are arranged alternately, in a row at a lower side of the drawing of the quantum chip 101. As in the above, this configuration also contributes to reduce an effect of crosstalk between lines transmitting the same type of signal (e.g., signal wave).

From another viewpoint, a pump terminal to which a pump line is connected or a control terminal to which a control line is connected, is disposed between IO terminals to which IO lines are connected. This configuration can reduce an effect of crosstalk between the IO lines. From yet another viewpoint, a pump terminal(s) to which pump line(s) is/are connected, or a control terminal(s) to which control line(s) is/are connected, are disposed on both sides of an IO terminal to which an IO line is connected. This configuration can reduce an effect of crosstalk that the IO line receives from other IO lines.

At an outer edge portion (chip periphery) of the wiring layer of the quantum chip 101,
an IO terminal, connected to a second end of an IO line with a first end thereof connected to a capacitively coupled port a of the JPO 2;
a control terminal connected to a second end of a control line with a first end thereof connected to an inductively coupled port d of the coupler 2;
an IO terminal connected to a second end of an IO line with a first end thereof connected to a capacitively coupled port a of the JPO 4;
a pump terminal connected to a second end of a pump line with a first end thereof connected to an inductively coupled port b of the JPO 4;
an IO terminal connected to a second end of an IO line with a first end thereof connected to a capacitively coupled port c of the coupler 2; and
a pump terminal connected to a second end of a pump line with a first end thereof connected to an inductively coupled port b of the JPO 7, are lined up in a row from a top on a left side of the drawing of the quantum chip 101. An IO terminal (IO line) and a pump terminal/control terminal (pump line/control line) are arranged alternately (by turns). A pump terminal (pump line) is disposed between two IO terminals (IO lines).

Furthermore, at an outer edge portion (chip periphery) of the wiring layer of the quantum chip 101,
a pump terminal connected to a second end of a pump line with a first end thereof connected to an inductively coupled port b of the JPO 3;
an IO terminal connected to a second end of an IO line with a first end thereof connected to a capacitively coupled port c of the coupler 3;
a pump terminal connected to a second end of a pump line with a first end thereof connected to an inductively coupled port b of the JPO 6;
a control terminal connected to a second end of a control line with a first end thereof connected to an inductively coupled port d of the coupler 3; and
an IO terminal connected to a second end of an IO line with a first end thereof connected to a capacitively coupled port a of the JPO 8, are lined up in a row from a top on a right side of the drawing of the quantum chip 101. A pump terminal/control terminal (pump line/control line) and an IO terminal (IO line) are arranged alternately (by turns). A pump terminal (pump line) is disposed between two IO terminals (IO lines). In FIG. 1, focusing on one IO terminal (IO line) at the entire outer edge of the wiring layer of the quantum chip 101, a pump terminal (pump line) is disposed on each side of the IO terminal (IO line), or a pump terminal (pump line) and a control terminal (control line) are disposed on both sides of the IO terminal (IO line), respectively. Focusing on one pump terminal (pump line), an IO terminal (IO line) is disposed on each side of the pump terminal (pump line). Focusing on one control line, an IO terminal (IO line) is disposed on each side of the control terminal (control line).

A ground (GND) plane (ground pattern) is formed in a wiring layer on a surface of the quantum chip 101. The ground (GND) plane surrounds each of JPOs, couplers, and terminals (IO terminal, pump terminal, and control terminal). Edges of each JPO, each coupler, and each terminal face a corresponding edge of the GND plane via a gap. An IO line and/or a pump line (transmission line) may be configured as a coplanar line with both longitudinal sides (or both sides in the longitudinal direction) facing edges of the GND plane via gaps.

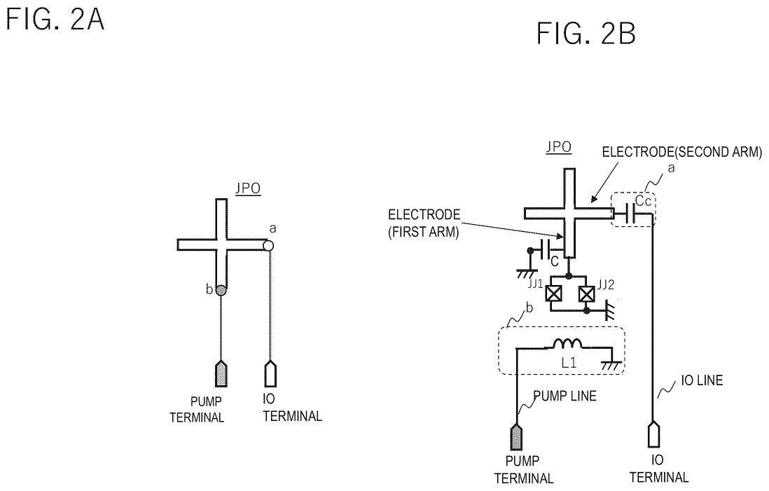

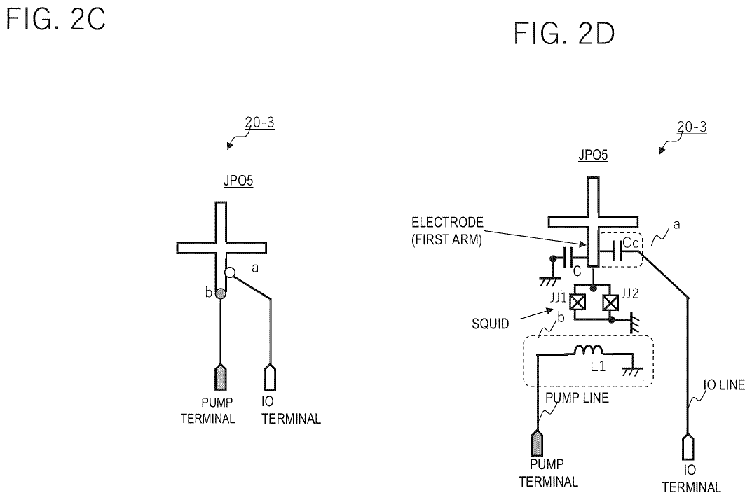

A configuration, in which an IO line and a pump line are provided at an end of a first arm of a cross-shaped electrode of a JPO and at an end of a second arm which is orthogonal to the first arm, respectively (FIG. 2A), such as JPOs 1-4 and JPOs 6-8 in FIG. 1, corresponds to a circuit connection as illustrated in FIG. 2B, for example. In FIG. 2A and FIG. 2B, “a” in JPO represents a coupling port (capacitively coupled port) that is capacitively coupled to the IO line, and “b” in JPO represents a coupling port (inductively coupled port) that is inductively coupled to the pump line.

As illustrated in FIG. 2B, a cross-shaped electrode made of four arms in JPO has inductance and capacitance to ground. The JPO is provided with a SQUID (including Josephson junctions JJ1 and JJ2 in a loop) connected between one end of a first arm and ground. Capacitor C represents a capacitance component to ground. A magnetic field generation portion (inductor L1) of a pump line with one end connected to ground, generates a magnetic flux (magnetic field) penetrating through the loop of the SQUID of the JPO by a pump wave (current) supplied from a pump terminal. In FIG. 2B, the SQUID includes two Josephson junctions JJ1 and JJ2 in the loop, but the SQUID may be configured to include three or more Josephson junctions. An IO line is capacitively coupled via a coupling capacitor Cc to one end of a second arm of the cross-shaped electrode of the JPO.

JPO 5 in FIG. 1, in which ends of three of four arms of a cross-shaped electrode are capacitively coupled to couplers 1, 2, and 3, respectively, corresponds to a configuration illustrated in FIG. 2C. In this case, as illustrated in FIG. 2D, JPO 5 is configured such that a coupling port of an IO line and a coupling port of a pump line in JPO5 are disposed respectively at an end and on a side of one remaining arm (first arm) of the four arms of the cross-shaped electrode. An IO line is capacitively coupled to the edge the remaining arm (first arm) of the cross-shaped electrode via a coupling capacitor Cc, as illustrated in FIG. 2D.

The substrate of the quantum chip includes, for example, silicon (Si). The substrate of the quantum chip is not limited to those including silicon and may include those including other electronic materials such as sapphire or compound semiconductor materials (Groups IV, III-V, and II-VI). The substrate of the quantum chip is preferably a single-crystalline material. Alternatively, the substrate may be a polycrystalline material or an amorphous material. A pattern on the wiring layer of the quantum chip can be formed, for example, by deposition (vapor deposition) of a superconducting material on a surface of the substrate and patterning the superconducting material. As a superconducting material (wiring material), Nb (niobium) or Al (aluminum) may be used, though not limited thereto. Any metal that becomes superconductive at an extremely low temperature (cryogenic temperature) may be used, such as niobium nitride, indium (In), lead (Pb), tin (Sn), rhenium (Re), palladium (Pd), titanium (Ti), titanium nitrides, molybdenum (Mo), tantalum (Ta), tantalum nitride, and an alloy containing at least one of the above metals. As a non-limiting example, Josephson junctions (Al/AlOₓ/Al) may be formed by forming a first aluminum film on a surface of the substrate of the quantum chip by oblique deposition, oxidizing the first aluminum film to form a tunnel oxide film (AlOₓ), and then forming a second aluminum film by oblique deposition from a direction opposite to a direction when the first aluminum film was formed.

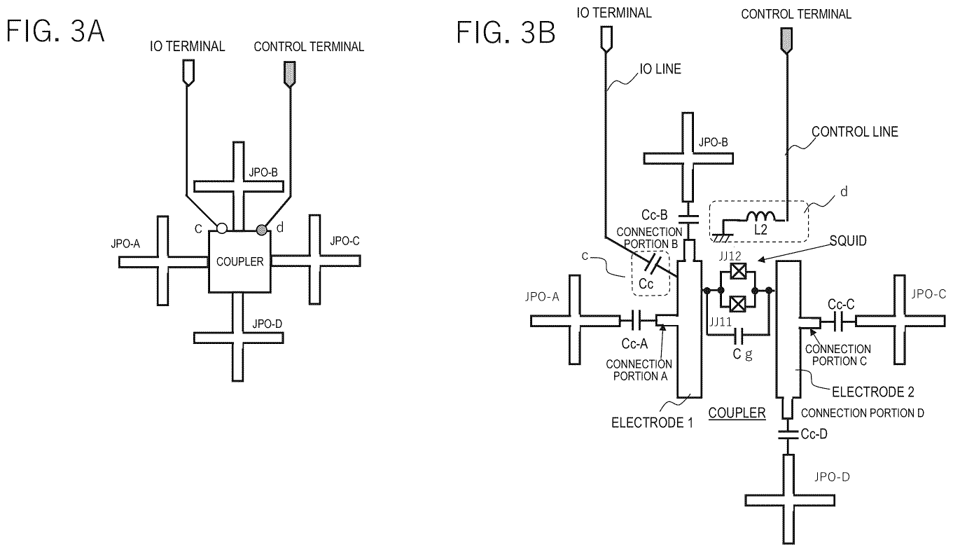

FIGS. 3A and 3B are diagrams illustrating a circuit connection of the coupler illustrated in FIG. 1. In FIG. 1, FIG. 3A and FIG. 3B, “c” represents a coupling port (capacitively coupled port) of an IO line to the coupler, and “d” represents a coupling port (inductively coupled port) of a control line to the coupler. As a non-limiting example, in an example illustrated in FIG. 3B, the coupler is provided with a SQUID (loop including Josephson junctions JJ11 and JJ12) between opposing electrode 1 and electrode 2, and a capacitor Cg is connected in parallel to the SQUID. The capacitor Cg is a capacitance component between the electrode 1 and the electrode 2. In FIG. 3B, when the SQUID is illustrated in correspondence with the size of the electrodes, it is difficult to clearly indicate the circuit connections on the drawing. Thus, the size (width and length) of SQUID and spacing between electrodes are enlarged to have approximately the same as or comparable to the electrodes 1 and 2, for drawing convenience. A magnetic field generation portion (inductor L2) of a control line, which is connected to ground at one end, generates a magnetic flux (magnetic field) penetrating through the loop of the SQUID of the coupler by a DC signal (DC current) supplied from a pump terminal. In the example illustrated in FIG. 3A and FIG. 3B, an IO line is capacitively coupled to the electrode 1 via a coupling capacitor. The electrode 1 of the coupler has a connection portion (protrusion) A, which is capacitively coupled via a coupling capacitor Cc-A to one end of a cross-shaped electrode of the JPO-A, and a connection portion (protrusion) B, which is capacitively coupled via a coupling capacitor Cc-B to one end of a cross-shaped electrode of the JPO-B. The electrode 2 of the coupler has a connection portion (protrusion) C, which is capacitively coupled via a coupling capacitor Cc-C to one end of a cross-shaped electrode of the JPO-C, and a connection portion (protrusion) D, which is capacitively coupled via a coupling capacitor Cc-D to one end of a cross-shaped electrode of the JPO-D. Note that, the JPO-A to the JPO-D in FIG. 3A and FIG. 3B are one of (JPO 2, JPO 1, JPO 3, and JPO 5), (JPO 4, JPO 2, JPO 5, and JPO 7), and (JPO 5, JPO 3, JPO 6, and JPO 8) in FIG. 1.

Referring again to FIG. 1, the IO line and the control line of each coupler are extended on the ground plane (GND plane) between outer JPOs to connect respectively with the IO terminal and the control terminal on a periphery of a chip. For example, the IO line connected to the capacitively coupled port (IO port) c of the coupler 1 is extended through the ground plane (GND plane) between the JPO 1 and the JPO 2 to connect with the IO terminal at the upper side of the drawing. The control line connected to the inductively coupled port (control port) d of the coupler 1 is extended through the ground plane (GND plane) between the JPO 1 and the JPO 3 to connect with the control terminal at the upper side of the drawing. The IO line connected to the capacitively coupled port c of the coupler 2 is extended through the ground plane (GND plane) between the JPO 4 and the JPO 7 to connect with the IO terminal at the left side of the drawing. The control line connected to the inductively coupled port d of the coupler 2 is extended through the ground plane (GND plane) between the JPO 2 and the JPO 4 to connect with the control terminal at the left side of the drawing. The IO line connected to the capacitively coupled port c of the coupler 3 is extended through the ground plane (GND plane) between the JPO 3 and the JPO 6 to connect with the IO terminal at the right side of the drawing. The control line connected to the inductively coupled port d of the coupler 3 is extended through the ground plane (GND plane) between the JPO 6 and the JPO 8 to connect with the control terminal at the right side of the drawing. The IO lines and the control lines of the couplers 1, 2, and 3 and the IO line and the pump line of the JPO 5 may be configured to change angles in directions of extension in a region between the JPOs arranged on an outer edge side to ensure a distance (space) between adjacent lines.

In FIG. 1, an example in which all IO lines and pump lines of the JPOs and the couplers are arranged alternately in the quantum chip 101 is illustrated. However, instead of alternate placing of IO line and pump line for all lines, some pairs of lines of similar type having a crosstalk effect, such as a pair of lines on which signals with significantly different frequencies are transmitted, may be disposed next to each other. Since on the control line of the coupler, only DC current is flown, crosstalk of AC current may be unlikely to occur even when the control line of the coupler is placed adjacently to the pump line of the JPOs. FIG. 1 illustrates an example of wiring and placement of the quantum chip 101 in which a set of all adjacent three lines has a pattern of either,
(1) a pump line connecting to a JPO or a control line connecting to a coupler being disposed between an IO line and another IO line, or
(2) a pump line connecting to a JPO and/or a control line connecting to a coupler being disposed on both sides of an IO line.

However, for the reason described above, there may be such a pattern(s) in which,
(3) pump line(s) and/or IO line(s) connecting to a JPO(s) are disposed on both sides of a control line connecting to a coupler, and/or
(4) two or more of the adjacent three lines are control lines connecting to couplers. That is, the arrangement of a set of all adjacent three lines is preferably one of (1) to (4) above, and more preferably one of (1) and (2) above.

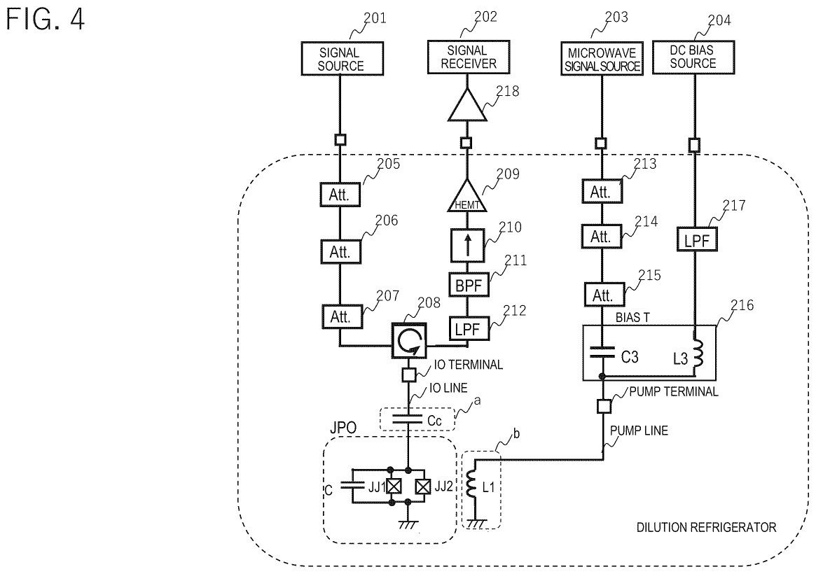

FIG. 4 is a diagram illustrating an example of a connection configuration of an IO terminal and a pump terminal to which an IO line and a pump line of the JPO connects respectively, and measurement electronics outside a refrigerator. Referring to FIG. 4, the IO line has a first end connected to the JPO via a coupling capacitor Cc, and a second end connected to a circulator 208 via the IO terminal. A signal from a signal source 201 outside a dilution refrigerator is transmitted through a coaxial cable which is led into the dilution refrigerator, is attenuated gradually by attenuators (Atts.) 205, 206, and 207 installed at respective temperature stages, and transmitted, via the circulator 208, to the IO terminal, from which the signal (input signal) is supplied to the JPO. An output signal wave from the JPO or a reflection signal of the input signal wave from the JPO is transmitted from the IO terminal via the circulator 208, a Low Pass Filter (LPF) 212, a Band Pass Filter (BPF) 211, an isolator 210 and a HEMT (High Electron Mobility Transistor) amplifier 209 to an amplifier 218 outside the dilution refrigerator, which supplies an amplified signal to a signal receiver 202. A pump signal (microwave continuous wave or pulsed wave) from a microwave signal source 203, which generates the pump signal, is transmitted through a coaxial cable which is led into the dilution refrigerator, attenuated gradually by attenuators 213, 214, and 215 installed at respective temperature stages and supplied to a bias T circuit 216. A DC (Direct Current) signal from a DC bias source 204 is supplied through a transmission line (e.g., twisted pair) which is led into the dilution refrigerator to the bias T circuit 216 via an LPF 217. The bias T circuit 216 includes a capacitor C3 and an inductor L3 (choke coil). The capacitor C3 has one end to receive a microwave from the microwave signal source 203. The inductor L3 (choke coil) has one end to receive the DC signal from the DC bias source 204 via the LPF 217. A connection point of other ends of the capacitor C3 and the inductor L3 is connected to a pump line. The bias T circuit 216 superimposes (combines) a direct current signal on a high-frequency signal for supply to the pump line. The capacitor C3 passes only high frequencies. The inductor L3 passes a direct current and a current with a frequency lower than a prescribed frequency and blocks a current with a frequency higher than the prescribed frequency. That is, the JPO can perform parametric oscillation at a frequency (angular frequency) w by supplying a DC bias signal and a pump signal to the pump line from the microwave signal source 203. The DC bias signal is a signal for biasing the SQUID in the JPO with a DC magnetic flux. The pump signal has a frequency about twice the resonant frequency (angular frequency) w of the SQUID resonator.

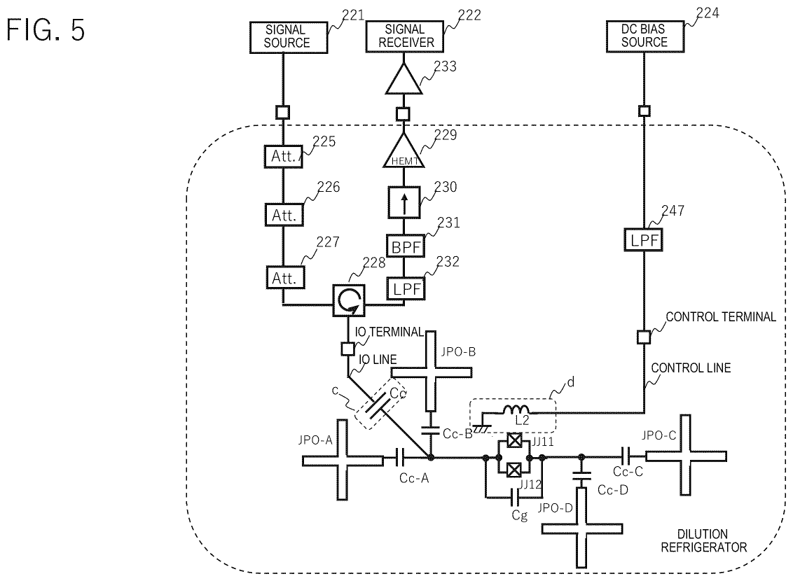

FIG. 5 is a diagram illustrating an example of a connection configuration of an IO terminal and a pump terminal to which an IO line and a pump line of the coupler connects respectively, and measurement electronics outside a refrigerator. Referring to FIG. 5, the IO line has one end connected to the coupler via a coupling capacitor Cc (port c) and the other end connected to a circulator 228 via the IO terminal. A signal from a signal source 221 outside a dilution refrigerator is transmitted through a coaxial cable which is led into the dilution refrigerator, is attenuated gradually by attenuators (Atts.) 225, 226, and 227 installed at respective temperature stages, and is transmitted to the IO terminal via the circulator 228, from which the signal (input signal) is supplied to the coupler. A reflection signal of the input signal wave from the coupler is transmitted from the IO terminal via the circulator 228, a Low Pass Filter (LPF) 232, a Band Pass Filter (BPF) 231, an isolator 230 and a HEMT amplifier 229 to an amplifier 233 outside the dilution refrigerator, which supplies an amplified signal to a signal receiver 222. A DC signal from a DC bias source 224 is transmitted through a transmission line (e.g., twisted pair) which is led into the dilution refrigerator, supplied to the control terminal via an LPF 247, from which the DC signal is supplied via the control line to an inductor L2 (port d).

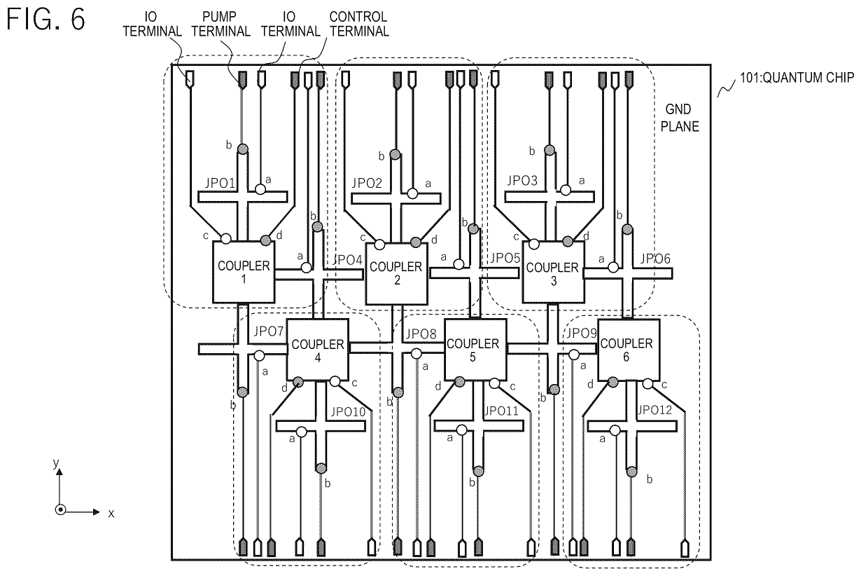

FIG. 6 schematically illustrates another example of a circuit pattern (placement and wiring) of the wiring layer on the substrate surface of the quantum chip 101. Referring to FIG. 6, as with FIG. 1, four JPOs and a coupler to which the four JPOs are capacitively coupled form a unit structure (basic unit), which can be scaled up (or out) in the lateral direction only by planer wiring. A repeating unit of a line arrangement may be configured with an IO line of the coupler, a pump line of a JPO connected to the coupler, an IO line of the JPO, a control line of the coupler, an IO line of another JPO connected to the coupler, and a pump line of the other JPO. For example, in the upper half of the drawing of the quantum chip 101, the IO line of the coupler 1, the pump line of the JPO1, the IO line of the JPO1, the control line of the coupler 1, the IO line of the JPO4, and the pump line of the JPO4 configure the repeating unit. The IO line of the coupler 2, the pump line of the JPO2, the IO line of the JPO2, the control line of the coupler 2, the IO line of the JPO5, and the pump line of the JPO5 configure the repeating unit. The IO line of the coupler 3, the pump line of the JPO3, the IO line of the JPO3, the control line of the coupler 3, the IO line of the JPO6, and the pump line of the JPO6 configure the repeating unit. The same applies to the couplers 4, 5, 6 and the JPO 7 to JPO 12 located in the lower half of the drawing of the quantum chip 101.

Each IO line and each pump line of the JPOs 1 to 6 and each IO line and each control line of the couplers 1 to 3 are connected to an IO terminal and a pump terminal/control terminal on an upper side of the drawing of the quantum chip 101, respectively. Each IO line and each pump line of the JPOs 7 to 12 and each IO line and each control line of the couplers 4 to 6 are connected to an IO terminal and a pump terminal/control terminal on a lower side of the drawing of the quantum chip 101, respectively. In the example illustrated in FIG. 6, coupling ports with IO lines (capacitively coupled ports indicated by white circles) in cross-shaped electrodes of JPOs 1 to 3 and JPOs 10 to 12 are disposed respectively on sides of lateral arms of the cross-shaped electrodes. As illustrated in FIG. 2A, the coupling port with the IO line may, as a matter of course, be provided at an end of the arm. In the example illustrated in FIG. 6, in the JPOs 4, 5, 8 and 9, in which ends of three of four arms of each cross-shaped electrode are capacitively coupled to three couplers, respectively, the coupling ports (capacitively coupled ports) with IO lines, indicated by white circles, are provided respectively on sides of the arms whose ends are capacitively coupled to the couplers. However, as illustrated in FIG. 2C, the coupling port (capacitively coupled port) with IO line may be provided on a side of one remaining arm, one end of which is a coupling port (gray circle) inductively coupled to the pump line.

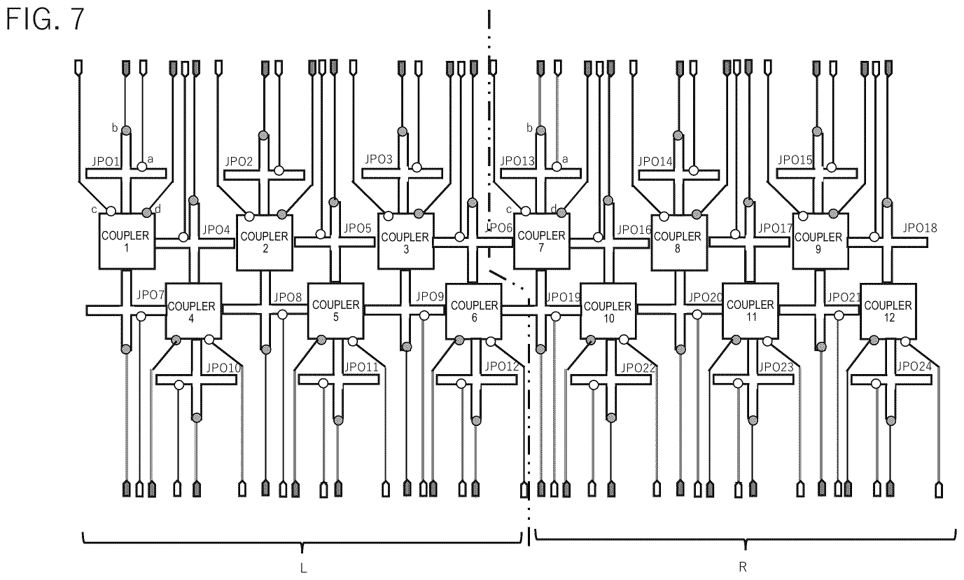

FIG. 7 is a diagram illustrating an example in which configuration illustrated in FIG. 6 is expanded (scaled-out) in the lateral direction. The configuration illustrated in FIG. 6 is disposed (duplicated) in the lateral direction as it is. A network of 24 JPOs and 12 couplers is formed by wiring with which an end of the lateral arm of a cross-shaped electrode of the JPO 6 is capacitively coupled to the coupler 7, and an end of the lateral arm of a cross-shaped electrode of the JPO 19 is capacitively coupled to the coupler 6. IO terminals and pump terminals/control terminals are disposed on the upper side and the lower side. For this reason, wiring in the longitudinal direction for scale-out is not required. To expand (scale-out) the configuration illustrated in FIG. 6 to the lateral direction, a circuit pattern may be created by arranging the configuration illustrated in FIG. 6 in parallel in the lateral direction as a wiring layer of the quantum chip 101. Alternatively, the scaled-out may be implemented by disposing a plurality of quantum chips 101 each having a configuration illustrated in FIG. 6 in the lateral direction (laterally).

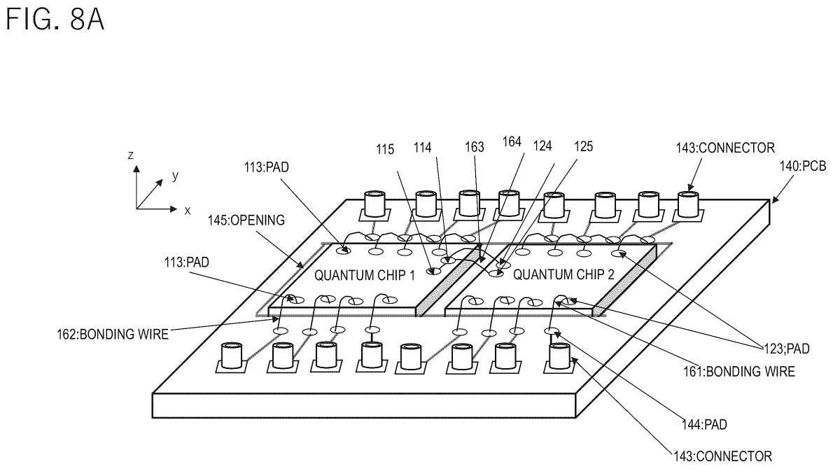

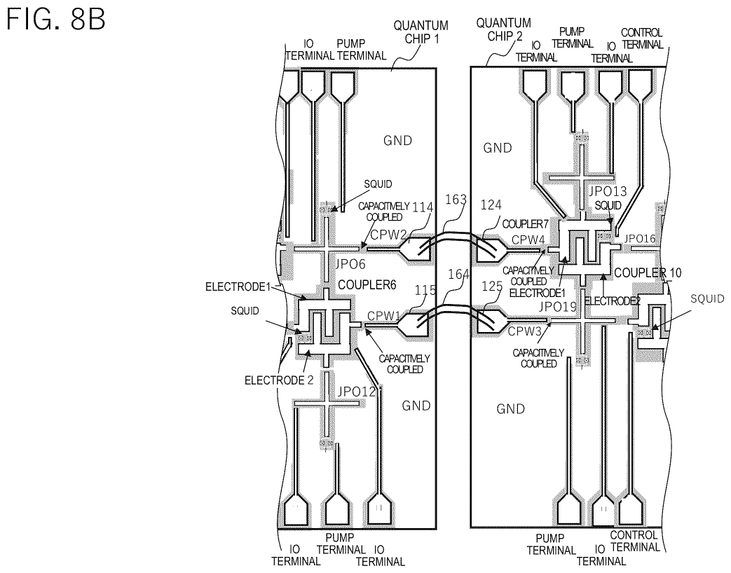

FIG. 8A is a diagram illustrating one example of a configuration in which two quantum chips 101 illustrated in FIG. 6 are arranged in the lateral direction, as an example of the scale-out of the quantum chip 101. A quantum chip 1 and a quantum chip 2 are both identical to the quantum chip 101 illustrated in FIG. 6. A row of pads 113 of the quantum chip 1 is a row of alternately arranged IO terminals and pump terminals/control terminals as illustrated in FIG. 6. A row of pads 123 of the quantum chip 2 is a row of alternately arranged IO terminals and pump terminals/control terminals as illustrated in FIG. 6. In FIG. 8A, only four pads are illustrated on an opposed side of the quantum chip 1 as the pads 113. Also, only four pads are illustrated on an opposed side of the quantum chip 2 as the pads 123. In FIG. 8A, only for the sake of simplicity, the number of pads 113 (123) do not correspond to the number of the IO terminals and the pump terminals on the upper side and the bottom side of the quantum chip 101 illustrated in FIG. 6.

The pads 113 of the quantum chip 1 and the pads 123 of the quantum chip 2 are connected to pads 144 of a PCB (printed circuit board) 140 with bonding wires 161. Each pad 144 is wired to corresponding connectors 143. The connectors 143 may include, for example, a high-frequency coaxial connector. The connector 143 may be connected to a coaxial cable laid inside a refrigerator and connected to a measurement electronics outside the refrigerator.

Referring to FIG. 8A, pads provided on the quantum chip 1 are connected to pads of the quantum chip 2 by bonding wires. In this configuration, there is provided wiring for capacitively coupling an end of the lateral arm of the cross-shaped electrode of the JPO 6 on an L side in FIG. 7 to the coupler 7 on a R side in FIG. 7, and wiring for capacitively coupling an end of the lateral arm of the cross-shaped electrode of the JPO 19 on the R side in FIG. 7 to the coupler 6 on the L side in FIG. 7. Here, the JPO 6 and the coupler 6 are disposed in the quantum chip 1 and the coupler 6 and the JPO 19 are disposed in the quantum chip 2. In the quantum chip 1, the end of the lateral arm of the cross-shaped electrode of the JPO 6 is connected to a pad 114, and in quantum chip 2, a line capacitively coupled to an electrode of the coupler 7 is connected to a pad 124. The pad 114 of the quantum chip 1 is connected to the pad 124 of the quantum chip 2 by a bonding wire 163. The JPO 6 is JPO 6 on the L side in FIG. 7 and the coupler 7 is the coupler 7 on the R side in FIG. 7. In the quantum chip 1, a line that capacitively couples to an electrode of the coupler 6 is connected to a pad 115, and in quantum chip 2, the end of the lateral arm of the cross-shaped electrode of the JPO 19 is connected to a pad 125. The pad 115 of the quantum chip 1 is connected to the pad 125 of the quantum chip 2 by a bonding wire 164. Here, the coupler 6 is the coupler 6 on the L side in FIG. 7 and the JPO 19 is the JPO 19 on the R side in FIG. 7.

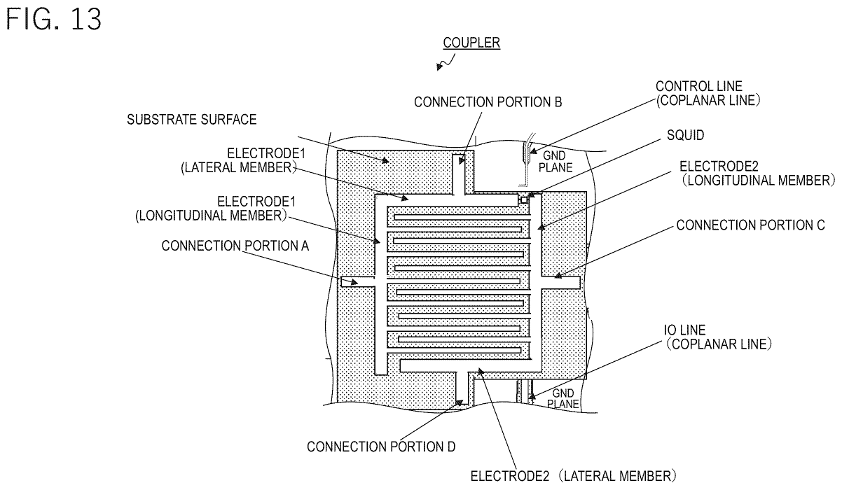

FIG. 8B is a diagram illustrating circuit patterns of the quantum chip 1 and the quantum chip 2 described with reference to FIG. 8A. In FIG. 8B, a part of circuit patterns where a circuit on the left (L) side of FIG. 7 is mounted on the quantum chip 1 and a circuit on the right (R) side of FIG. 7 is mounted on the quantum chip 2 is illustrated. In FIG. 8B, as the wiring layer on a substrate of the quantum chip 1, a part of patterns of the coupler 6, the JPO 6, the JPO 12, each wiring and each pad (terminal) in the circuit on the L side of FIG. 7 are schematically illustrated, and as the wiring layer on a substrate of the quantum chip 2, an example of patterns of the coupler 7, the JPO 13, the JPO 19, each wiring and each pad (terminal) in the circuit on the R side of FIG. 7 is schematically illustrated. As illustrated schematically in FIG. 8B, a ground plane (GND) is arranged opposing (surrounding) each one of couplers, JPOs, wirings, and terminals, via a gap. In FIG. 8B, the gap is illustrated in gray and represents an exposed portion of a surface of the substrate. The couplers are configured as illustrated in FIG. 13, which will be described later. In FIG. 8B, electrodes of the coupler with nested structure are illustrated in simplified form. In the quantum chip 1, an end of a connection portion of an electrode 2 of the coupler 6 is arranged opposing one end of a Coplanar Wave Guide CPW 1 and capacitively coupled to CPW 1 which has the other end connected to the pad 115. The pad 115 is connected to the pad 125 of the quantum chip 2 by the bonding wire 164. One end of a CPW 3 with the other end connected to the pad 125, is arranged opposing an end of the lateral arm of the cross-shaped electrode of the JPO 19 and capacitively coupled to the electrode of the JPO 19. In the quantum chip 1, an end of an arm of the JPO 6 is arranged opposing one end of a CPW 2 and capacitively coupled to the CPW 2 which has the other end connected to the pad 114. The pad 114 is connected to the pad 124 of the quantum chip 2 by the bonding wire 163. One end of a CPW 4 with the other end connected to the pad 124, is arranged opposing an end of a connection portion of an electrode 1 of the coupler 7 and capacitively coupled to the electrode 1. Each of structures below should preferably be as short as possible in length, taking into account an effect of stray capacitance and other factors. [CPW 1]-[pad 115]-[bonding wire 164]-[pad 125]-[CPW3], and [CPW 2]-[pad 114]-[bonding wire 163]-[pad 124]-[CPW 4]

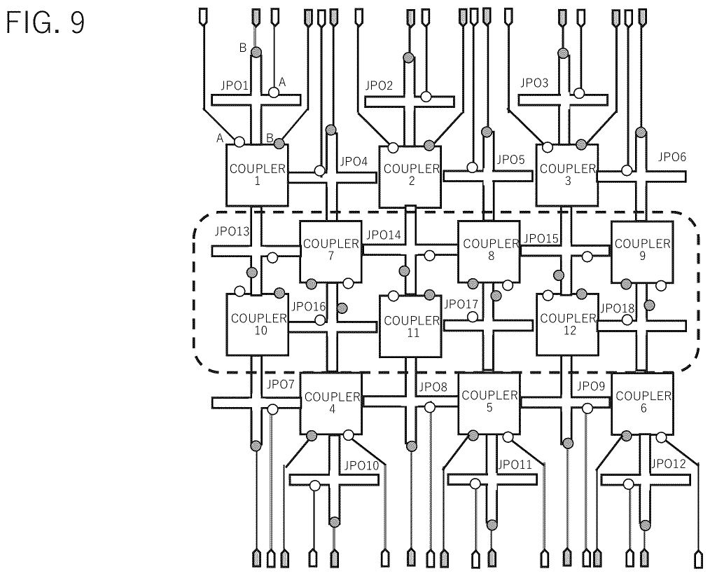

FIG. 9 is a diagram illustrating an example of a configuration illustrated in FIG. 6 expanded in the longitudinal direction. Referring to FIG. 9, an expansion portion (couplers 7 to 12 and JPOs 13 to 18) enclosed by dashed lines are added between the couplers 1 to 3 and the JPOs 1 to 6 and the couplers 4 to 6 and the JPOs 7 to 12 in FIG. 6.

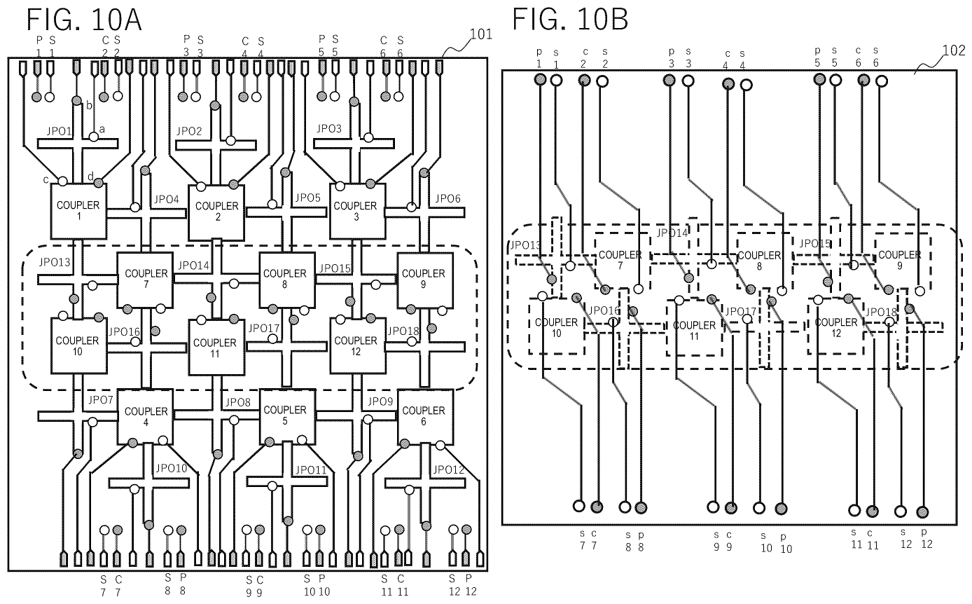

IO lines and control lines of the added couplers 7 to 12 and IO lines and pump lines of the added JPOs 13 to 18 are connected from an IO port c (white circle) and a pump port d (gray circle) of each coupler and an IO port (capacitively coupled port; white circle) and a pump port (inductively coupled port; gray circle) of each JPO to a wiring layer of a corresponding wiring chip 102 by bumps (e.g., metal protrusions; not shown) as illustrated in FIG. 10B. IO lines and control lines/pump lines of the added couplers and JPOs are routed to pads (p1, s1) and (c2, s2) to (c6, s6), and pads (s7, c7) and (s8, p8) to (s12, p12) by the wiring of the wiring layer of the wiring chip 102. FIG. 10B schematically illustrates an example of a wiring pattern of the wiring chip 102 arranged facing the quantum chip 101 via a bmp. In FIG. 10B, the couplers 7 to 12 and the JPOs 13 to 18 of the quantum chip 101 are illustrated as dashed lines, and the example of the wiring pattern of the wiring chip 102 is illustrated corresponding to the couplers and the JPOs of the quantum chip 101.

Referring to FIG. 10B, in the wiring layer of the wiring chip 102, pads (p1, s1), (c2, s2) to (c6, s6) and pads (s7, c7), (s8, p8) to (s12, p12) are connected to the wiring layer of the quantum chip 101 with bumps. Between the IO terminal and the pump terminal of each of the couplers 1 to 3 and JPOs 1 to 6, couplers 4 to 6 and JPOs 7 to 12, there are provided the terminal and the pump terminal connected to the IO line and the pump line/control line of each of the couplers 7 to 12 and JPOs 13 to 18, which are connected via bumps to the wiring layer of the wiring chip (interposer) 102.

In an example illustrated in FIG. 10A, between the IO terminal to which the IO line of the coupler 1 is connected and the pump terminal to which the pump line of the JPO 1 is connected, a pump terminal and an IO terminal (P1, S1) to which the pump line and the IO line of the JPO 13 are connected, respectively, are placed. Between the IO terminal to which the IO line capacitively couples to the lateral arm of the cross-shaped electrode of the JPO 1 and the control terminal to which the control line of the coupler 1 is connected, a control terminal and an IO terminal (C2, S2) to which the control line and the IO line of the coupler 7 are connected, respectively, are placed. Between the IO terminal to which the IO line of the coupler 2 is connected and the pump terminal to which the pump line of the JPO 2 is connected, a pump terminal and an IO terminal (P3, S3) to which the pump line and the IO line of the JPO 14 are connected, respectively, are placed. Between the IO terminal to which the IO line capacitively couples to the lateral arm of the cross-shaped electrode of the JPO 2 and the control terminal to which the control line of the coupler 2 is connected, a control terminal and an IO terminal (C4, S4) to which the control line and the IO line of the coupler 8 are connected, respectively, are placed. Between the IO terminal to which the IO line of the coupler 3 is connected and the pump terminal to which the pump line of the JPO 3 is connected, a pump terminal and an IO terminal (P5, S5) to which the pump line and the IO line of the JPO 15 are connected, respectively, are placed. Between the IO terminal to which the IO line capacitively couples to the lateral arm of the cross-shaped electrode of the JPO 3 and the control terminal to which the control line of the coupler 3 is connected, a control terminal and an IO terminal (C6, S6) to which the control line and the IO line of the coupler 9 are connected, respectively, are placed.

Between the control terminal to which the control line of the coupler 4 is connected and the IO terminal to which the IO line capacitively couples to the lateral arm of the cross-shaped electrode of the JPO 10, an IO terminal and a control terminal (S7, C7) to which the IO line and the control line of the coupler 10 are connected, respectively, are placed. Between the pump terminal to which the pump line of the JPO 10 is connected and the IO terminal to which the IO line of the coupler 4 is connected, an IO terminal and a pump terminal (S8, P8) to which the IO line and the pump line of the JPO 16 are connected, respectively, are placed. Between the control terminal to which the control line of the coupler 5 is connected and the IO terminal to which the IO line capacitively couples to the lateral arm of the cross-shaped electrode of the JPO 11, an IO terminal and a control terminal (S9, C9) to which the IO line and the control line of the coupler 11 are connected, respectively, are placed. Between the pump terminal to which the pump line of the JPO 11 is connected and the IO terminal to which the IO line of the coupler 5 is connected, an IO terminal and a pump terminal (S10, P10) to which the IO line and the pump line of the JPO 17 are connected, respectively, are placed. Between the control terminal to which the control line of the coupler 6 is connected and the IO terminal to which the IO line capacitively couples to the lateral arm of the cross-shaped electrode of the JPO 12, an IO terminal and a control terminal (S11, C11) to which the IO line and the control line of the coupler 12 are connected, respectively, are placed. Between the pump terminal to which the pump line of the JPO 12 is connected and the IO terminal to which the IO line of the coupler 6 is connected, an IO terminal and a pump terminal (S12, P12) to which the IO line and the pump line of the JPO 18 are connected, respectively, are placed.

A pair of a gray-circle pad and white-circle pad which are connected to a pair of an IO terminal and a pump terminal/control terminal (Si, Pi/Ci) (i=1 to 12, where (Si, Pi) for i=1, 3, 5, 8, 10, and 12, and (Si, Ci)) for i=2, 4, 6, 7, 9, and 11) in FIG. 10A, are connected via bumps to a pair of pads (si, pi/ci) (i=1 to 12, where (si, pi) for i=1, 3, 5, 8, 10, and 12, and (si, ci) for i=2, 4, 6, 7, 9, and 11), respectively, in the wiring chip 102 in FIG. 10B.

In FIG. 10B, the IO lines and the pump lines of the JPO 13 to 18 and the couplers 7 to 12 are connected to pads (p1, s1), (c2, s2) to (c6, s6) on the upper side of the drawing of the quantum chip 102 and connected to pads (s7, c7), (s8, p8) to (s12, p12) on the lower side of the drawing of the quantum chip 101. However, it can be configured that the IO lines and the pump lines of the JPOs 13, 14, and 16 and the couplers 7, 10 and 11 in the left half of FIG. 10B are connected to pads on the left side of the drawing of the quantum chip 102, the IO lines and the pump lines of the JPOs 15, 17, and 18 and the couplers 8, 9 and 12 in the right half of the drawing of the quantum chip 102 are connected to pads on the right side of the drawing of the quantum chip 102, each pad on the left side and the right side is connected to the wiring layer of the quantum chip 101 with bumps, the terminals (P1, S1) to (P3, S3) and (S7, C7) to (S9, C9) of FIG. 10A are disposed on the left side and terminals (C4, S4) to (C6, S6) and (S10, P10) to (S12, P12) are disposed on the right side.

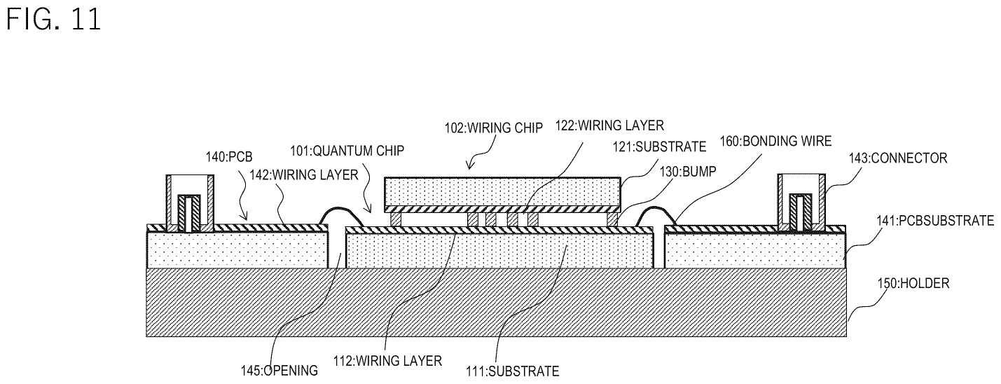

FIG. 11 is a schematic cross-sectional view illustrating a mounting example of the quantum chip 101 and the wiring chip 102 illustrated in FIG. 10A and FIG. 10B. In FIG. 11, a cross section of the quantum chip 101 corresponds to a cross section at a line connecting a terminal on the upper side of FIG. 10A and a terminal on the lower side corresponded. In a wiring layer 112 of the quantum chip 101, IO terminals and pump terminals/control terminals which are connected to IO lines and pump lines/control lines of an expansion portion (couplers 7 to 12 and JPOs 13 to 18) enclosed by the dashed line in FIG. 10A are inserted in an array of IO terminals and pump terminals/control terminals of the quantum chip 101. The IO terminals and pump terminals/control terminals inserted are connected to wiring pads on a wiring layer 122 of the wiring chip 102 from capacitively coupled port (IO port) and inductively coupled ports (pump ports/control ports) of the expansion portion with bumps 130. On the wiring layer 122 of the wiring chip 102, wirings are routed from the wiring pads to pads (p1, s1), (c2, s2) to (c6, s6), and pads (s7, c7), (s8, p8) to (s12, p12) of the wiring chip 102 (e.g., left side and right side of the drawing), and from the pads (p1, s1), (c2, s2) to (c6, s6), and the pads (s7, c7), (s8, p8) to (s12, p12), and are connected to the wiring layer 112 of the quantum chip 101 with bumps. The IO terminals and the pump terminals/control terminals of the quantum chip 101, which are formed as bonding pads. are connected to bonding pads of a wiring layer 142 of the PCB 140 with bonding wires 160 and are connected from the bonding pads to the connectors 143 (coaxial connectors, etc.). The connectors 143 are connected to the circulator 208 and/or the bias T circuit 216 illustrated in FIG. 4, and the circulator 228 and/or the DC circuit 216 illustrated in FIG. 5 via transmission lines (coaxial cable, etc.; not shown). A substrate 111 of the quantum chip 101 and a substrate 121 of the wiring chip 102 are preferably made of the same material, such as a silicon substrate in consideration of a linear expansion coefficient and other factors. The wiring layer 112 of the quantum chip 101 and the wiring layer 122 of the wiring chip 102 are both made of superconducting materials (preferably the same material).

The bump 130 has a protrusive shape suited to height control of inter-substrate spacing to be bonded, and any shape can be selected, such as columnar (cylindrical, polygonal, etc.), pyramidal (which can include a truncated cone and a truncated pyramid as well as a cone, and a pyramid, etc.), spherical, rectangular, etc. The bump 130 may include normal-conducting material and laminated superconducting materials. The bump 130 may include the same superconducting material as the wiring layer 112 of the quantum chip 101. Alternatively, the bump 130 may include a superconducting material different from that of the wiring layer 112. Bonding of the quantum chip 101 and the bump 130 may be performed using solid phase bonding. A chamber of a refrigerator is evacuated. Among solid-phase bonding methods, surface activation bonding or ultrasonic bonding may be used. Melt joining may be used when high temperature can be applied during bonding. Pressure welding may be used when resin can be used.

In the example of FIG. 11, the quantum chip 101 is housed in an opening 145 provided in the PCB 140 which is mounted on a holder 150 with high thermal conductivity in charge of cooling. Alternatively, the quantum chip 101 may be mounted on the PCB 140. In the example of FIG. 11, the wiring chip 102 is placed on the quantum chip 101. However, the quantum chip 101 may be placed on an upper side and the wiring chip 102 (interposer) may be on a lower side. In this case, the wiring layer 112 of the quantum chip 101 faces downward and is connected via bumps to the wiring layer 122 of the wiring chip 102 (interposer). The terminals of the quantum chip 101 in FIG. 10A may be provided at a side of the wiring layer 122 of the wiring chip 102. As for the IO terminals and the pump terminals of the quantum chip 101 in FIG. 10A, the pads (P1, S1), (C2, S2) to (C6, S6) and the pads (S7, C7), (S8, P8) to (S12, P12) may be connected to IO terminals and the pump terminals on the wiring layer 122 of the wiring chip 102 by routing the pump lines/control lines and the IO lines on the wiring layer 122 of the wiring chip 102. The pump lines/control lines and the IO lines, which are connected to other terminals, may be connected to the wiring layer 122 of the wiring chip 102 with bumps from the wiring layer 112 of the quantum chip 101 to be connected to terminals on the wiring layer 122 of the wiring chip 102.

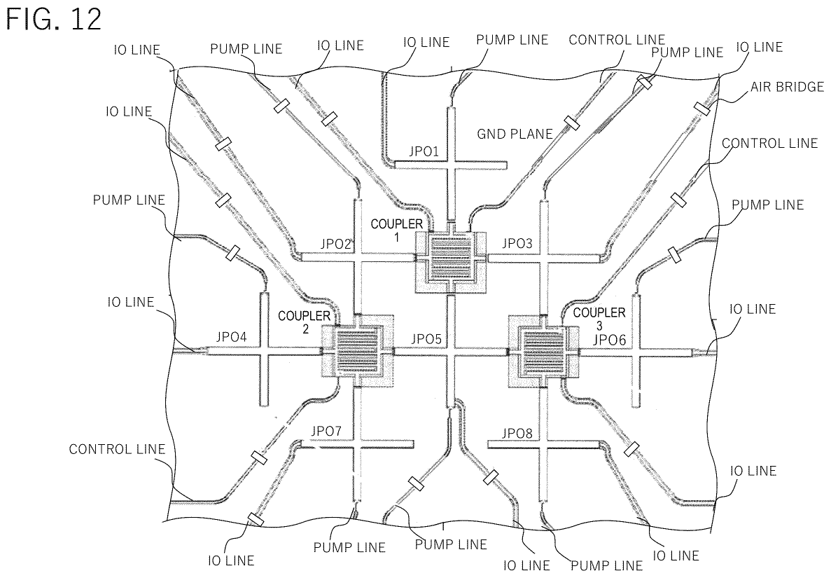

FIG. 12 illustrates a non-limiting example (a specific example of FIG. 1) and illustrates a circuit pattern of the wiring layer of the quantum chip 101 viewed from above. The circuit pattern can be formed, for example, by patterning a wiring layer made of superconducting material formed by for example, vapor-deposition on a substrate surface. In the example illustrated in FIG. 12, not all lines are arranged alternately with respect to the IO lines and the pump lines. The IO lines and the control lines are connected to the couplers 1, 2, and 3.

In FIG. 12, examples of sets in which the IO lines and the pump lines/control lines of the JPOs and the couplers are arranged alternately, are as follows.
an IO line of the coupler 2, a pump line of the JPO 4, an IO line of the JPO 4, a control line of the coupler 2, an IO line of the JPO 7, and a pump line of the JPO 7;
a pump line of the JPO 5, an IO line of the JPO 5, a pump line of the JPO 8, and an IO line of the JPO 8; and
an IO line of the JPO 2, a pump line of the JPO 2, and an IO line of the coupler 1.

An IO line and a pump line/control line of each coupler and each JPO may be configured as a coplanar line with both sides in the longitudinal direction facing a GND plane via gaps. An air bridge may be provided for the line. The air bridge with an overhead wiring striding over the coplanar line in a direction orthogonal to the longitudinal direction of the coplanar line has both ends connected to the GND plane. The air bridge may be made of the same superconducting material as the wiring layer 112 of the quantum chip 101. By connecting regions on both sides in the longitudinal direction of the line on the GND plane with the air bridge, the voltage distribution in the regions on both sides in the longitudinal direction of the line on the GND plane can be made uniform when a signal is transmitted on the line.

According to this example, crosstalk between lines of the same type can be reduced by an arrangement in which the IO lines and the pump lines/control lines of the JPOs and the couplers are placed alternately. Crosstalk between lines of different types has a smaller impact than that of the same type due to a difference in bandwidth between the input/output lines and the pump lines. In this case, parallel wiring may be used in a region where wiring is dense, such as between JPOs, and an angle between adjacent lines may be changed (e.g., 10 degrees or more) in regions outside the region between JPOs (where wiring is dense). This arrangement increases a distance (space) between lines on an outer edge side of a circuit surface of the quantum chip, thereby further reducing crosstalk. As a non-limiting example, in FIG. 12, a length of an arm of the cross-shaped electrode of each JPO is an order of several hundred ums (micrometers), and a width of the arm is approximately one sixth or one seventh of the length of the arm.

FIG. 13 is a diagram illustrating a specific example of a circuit pattern of one of the couplers illustrated in FIG. 12. The coupler includes electrode 1 and electrode 2, each of which has a longitudinal member and a lateral member and is L-shaped. The longitudinal members of the electrodes 1 and 2 are disposed opposed to each other, and the lateral members of the electrodes 1 and 2 are also disposed opposed to each other. Each of electrode 1 and electrode 2 is provided with rod-shaped (comb teeth-shaped) electrodes protruding from the longitudinal member toward the longitudinal member of the opposing electrode and has a shape in which the rod-shaped electrodes protruded from the longitudinal members of the electrodes 1 and 2 are arranged alternately (arranged facing to each other in a nested structure). There is provided a SQUID connected between the lateral member of the electrode 1 and the longitudinal member of the electrode 2. The longitudinal member and the lateral member of the electrode 1 include a connection portion A and a connection portion B (protrusion portions) that are capacitively coupled to a JPO-A and a JPO-B (not shown), respectively. The lateral member and the longitudinal member of the electrode 2 include a connection portion C and a connection portion D (protrusion portions) that are capacitively coupled with a JPO-C and JPO-D (not shown), respectively. In a vicinity of the SQUID, an end of a control line configured as a coplanar line is connected to the GND plane. That is, the end of the control line is configured to be bent at a right angle from a straight line which is extended in almost vertical direction in the drawing. The bent portion of the end of a control line be is elongated for a predetermined length in the lateral direction and comes into contact with the GND plane. An end of an IO line, which is capacitively coupled to the electrode 2, is disposed opposing the lateral member of the electrode 2. In regions other than where the end of the pump line inductively coupled to the SQUID and the end of the IO line capacitively coupled to the lateral member of the electrode 2 are disposed, a gap of a predetermined width is provided between the electrodes 1 and 2 and the GND plane that surrounds the electrodes 1 and 2, which reduces a capacitance between the GND and the electrodes 1 and 2. A surface of the substrate of the quantum chip 101 is exposed at each gap between the GND plane and each of the electrode 1, the electrode 2, the IO line and the pump line.

In FIG. 13, when the coupler is corresponded to a configuration of the coupler 3 in FIG. 12, the connection portion A, the connection portion B, the connection portion C, and the connection portion D capacitively couple to the JPO 5, the JPO 3, the JPO 6, and the JPO 8 in FIG. 12, respectively. The couplers 1 and 2 in FIG. 12 correspond to a pattern rotated by −90 degree from the coupler 3 in FIG. 12 and a pattern rotated by 180 degrees therefrom, respectively. The coupler, as a matter of course, not limited to the pattern illustrated in FIG. 13.

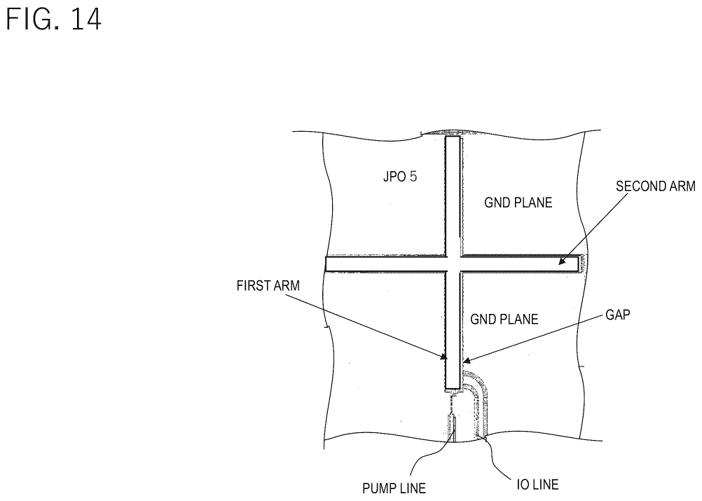

FIG. 14 is a diagram illustrating a non-limiting example of a pattern of the JPO 5 of FIG. 12. A SQUID is connected to an end of a first arm (vertical arm) of the cross-shaped electrode. Close to the SQUID, there is provided a magnetic field generation portion (an end portion of a coplanar pump line) with an end thereof connected to the GND plane. That is, the magnetic field generation portion of the end of the pump line is configured with a signal wiring which is bent from a straight line extended in almost vertical direction in the drawing and elongated for a predetermined length in the lateral direction to have an end in contact with the GND plane. A coplanar IO line has an end capacitively coupled to a middle portion of the first arm of the cross-shaped electrode. The IO line has an end flush with an edge of the GND plane provided on both sides of the IO line. The GND plane is disposed opposing the first arm of the cross-shaped electrode via a gap. A circuit configuration illustrated in FIG. 14 is identical to that illustrated in FIG. 2D.

In the above example embodiment, a JPO with a cross-shaped electrode is described as an electrode with four arms. However, other shapes can be used as the electrode with four arms. For example, four arms may protrude from a round, square, or other polygonal body, or there may be protrusions in addition to the four arms.

In the above examples of the disclosure, a qubit configured with a lumped element type JPO is described. However, the qubit may be configured with a distributed element type JPO.

The above examples of the disclosure can partially or entirely be described as following Supplementary notes (Notes), though not limited thereto.

### (Note 1)

A quantum device includes: a substrate; and a wiring layer formed on the substrate, wherein the wiring layer includes: a plurality of qubits;
a plurality of couplers, each connected to four of the plurality of qubits; a plurality of first lines, each capacitively coupled to each qubit; a plurality of second lines, each inductively coupled to each qubit; and a plurality of third lines, each capacitively coupled to each coupler; and a plurality of fourth lines, each inductively coupled to each coupler. A wiring pattern of the plurality of first lines and the plurality of second lines coupled to the plurality of qubits, respectively, and the plurality of third lines and the plurality of fourth lines coupled to the plurality of couplers, respectively, includes:
a first pattern that includes a pattern of adjacent three lines in which one of the second line and the fourth line is disposed between two lines selected from among the plurality of first lines and the plurality of third lines; and/or
a second pattern that includes a pattern of adjacent three lines in which two lines selected from among the plurality of second lines and the plurality of fourth lines are disposed on both sides of one of the first line and the third line.

### (Note 2)

A quantum device comprising: a substrate; and a wiring layer formed on the substrate, wherein the wiring layer incudes:
a plurality of qubits;
a plurality of couplers, each connected to four qubits;
a plurality of first lines, each capacitively coupled to each qubit;
a plurality of second lines, each inductively coupled to each qubit;
a plurality of third lines, each capacitively coupled to each coupler;
a plurality of fourth lines, each inductively coupled to each coupler;
a plurality of first terminals, each connected to a second end of each of the plurality of the first lines, a first end of each first line connected to a capacitive-coupling port of each of the plurality of qubits;
a plurality of second terminals, each connected to a second end of each of the plurality of the second lines, a first end of each second line connected to an inductive-coupling port of each of the plurality of qubits;
a plurality of third terminals, each connected to a second end of each of the plurality of third lines, a first end of each third line connected to a capacitive-coupling port of each of the plurality of couplers; and
a plurality of fourth terminals, each connected to a second end of each of the plurality of fourth lines, a first end of each fourth line connected to an inductive-coupling port of each of the plurality of couplers, wherein an arrangement pattern of three adjacent terminals among the first to fourth terminals includes:
a first arrangement pattern in which one of the second and fourth terminals is placed between two terminals selected from among the first and third terminals, and/or
a second arrangement pattern in which two terminals selected from among the second and fourth terminals are placed on both sides of one of the first and third terminals.

### (Note 3)

The quantum device according to Note 1, wherein the qubit includes an electrode that has at least first and second arms, wherein the second line is inductively coupled to a first SQUID (superconducting quantum interference device) disposed at the first arm, and the first line is capacitively coupled to the first arm or the second arm.

### (Note 4)

The quantum device according to Note 1 or 2, wherein at least one of the plurality of qubits has an electrode that has at least two arms, the second line is inductively coupled to a first superconducting quantum interference device disposed at one arm of the at least two arms, the first line is capacitively coupled to the one arm or an arm other than the one arm.

### (Note 5)

The quantum device according to any one of Notes 1 to 4, wherein the at least one of the first line, the second line, the third line, and the fourth line changes an angle in a direction of extension in a region exiting between the two elements to ensure a distance from a line adjacent to the at least one of the first line, the second line, the third line, and the fourth line.

### (Note 6)

The quantum device according to any one of Notes 1 to 5, wherein, for a third qubit and/or a third coupler that are blocked at least by a fourth coupler and/or a fourth qubit arranged in a vicinity of the third qubit and/or the third coupler, the first line and the second line coupled capacitively and inductively to the third qubit, respectively, and the third line and the fourth line coupled capacitively and inductively to the third coupler, respectively, are wired using a three-dimensional wiring, to a first terminal and a second terminal, and/or to a third terminal and a fourth terminal, disposed on the outer edge of the wiring layer, respectively.

### (Note 7)

The quantum device according to any one of Notes 1 to 5, comprising
a chip that includes:
first and second rows of terminals arranged along opposing first edge and second edge of the chip, each row including a first terminal, a second terminal, a third terminal, and a fourth terminal that are connected to the first line, the second line, the third line and the fourth line, respectively, and
between the first and second rows of terminals, a network circuit including at least one unit structure including four qubits and one coupler with at least one qubit of the unit structure shared by at least one other unit structure,
the chip configured to be scaled-out in one direction parallel to the first edge and the second edge.

### (Note 8)

The quantum device according to Note 7, wherein the quantum chip includes two or more coupling ports connected to a wiring layer of a wiring chip disposed opposing the quantum chip with first bumps, and through wiring routed on the wiring layer of the wiring chip, connected to the wiring layer of the quantum chip from the wiring layer of the wiring chip with second bumps to connect to at least one of the first terminal, the second terminal, the third terminal, and the fourth terminal of the first edge and the second edge, the coupling port being one of a plurality of coupling ports of the first line and the second line capacitively and inductively coupled to the qubit respectively, and the third line and the fourth line capacitively and inductively coupled to the coupler respectively, the coupler and the qubit included in the unit structure, arranged inner side of other unit structures disposed facing the first edge and the second edge, respectively.

### (Note 9)

The quantum device according to any one of Notes 1 to 8, comprising a plurality of a unit structure, each including four qubits and one coupler, wherein a quantum annealing machine is configured to have at least one qubit among the four qubits included one of the unit structures is shared by one or a plurality of other unit structures.

### (Note 10)

The quantum device according to any one of Notes 1 to 9, wherein the coupler comprises: opposing first and second electrodes; and a second superconducting quantum interference device connected between the first and second electrodes, the second superconducting quantum interference device including at least two Josephson junctions in a loop, wherein the third line is capacitively coupled to one of the opposing electrodes of the coupler, and a direct current is supplied to the fourth line inductively coupled to one of the opposing electrodes of the coupler to bias the second superconducting quantum interference device with a direct current magnetic flux.

### (Note 11)

The quantum device according to any one of Notes 1 to 10, wherein the qubit comprises a resonator including a first superconducting quantum interference device that includes at least two Josephson junctions in a loop, wherein a direct current bias signal and a microwave signal are supplied to the second line, the direct current flowing through the second line generating a direct magnetic flux bias penetrating through the first superconducting quantum interference device, the microwave signal flowing through to the second line generating an alternating magnetic flux penetrating through the first superconducting quantum interference device to cause the resonator to perform parametric oscillation.

The disclosure of each of NPLs 1 to 3 is incorporated herein by reference thereto. Variations and adjustments of the examples are possible within the scope of the overall disclosure (including the claims) based on the basic technical concept. Various combinations and selections of examples and disclosed elements (including the elements in each of the claims, examples, drawings, etc.) are possible within the scope of the claims of the present application. That is, the present disclosure includes various variations and modifications that could be made by those skilled in the art according to the overall disclosure including the claims and the technical concept.

What is claimed is:

1. A quantum device comprising:
a substrate; and
a wiring layer formed on the substrate, wherein the wiring layer includes:
a plurality of qubits;
a plurality of couplers, each connected to four of the plurality of qubits;
a plurality of first lines, each capacitively coupled to each qubit;
a plurality of second lines, each inductively coupled to each qubit; and
a plurality of third lines, each capacitively coupled to each coupler; and
a plurality of fourth lines, each inductively coupled to each coupler,
wherein a wiring pattern of the plurality of first lines and the plurality of second lines coupled to the plurality of qubits, respectively, and the plurality of third lines and the plurality of fourth lines coupled to the plurality of couplers, respectively, includes:
a first pattern that includes a pattern of adjacent three lines in which one of the second line and the fourth line is disposed between two lines selected from among the plurality of first lines and the plurality of third lines; and/or
a second pattern that includes a pattern of adjacent three lines in which two lines selected from among the plurality of second lines and the plurality of fourth lines, are disposed on both sides of one of the first line and the third line.

2. The quantum device according to claim 1, wherein the qubit includes
an electrode that has at least first and second arms,
wherein the second line is inductively coupled to a first SQUID (superconducting quantum interference device) disposed at the first arm, and
the first line is capacitively coupled to the first arm or the second arm.

3. The quantum device according to claim 1, wherein, for at least two elements including a second qubits and/or a second coupler disposed closer to an outer edge of the wiring layer than a first qubit and a first coupler, among the plurality of qubits and the plurality of couplers,
at least one of the first line and the second line connected to the first qubit, and the third line, and the fourth line connected to the first coupler is routed to extend through an area between the two elements and connect to at least one of a first terminal, a second terminal, a third terminal, and a fourth terminal disposed on the outer edge of the wiring layer.

4. The quantum device according to claim 3, wherein the at least one of the first line, the second line, the third line, and the fourth line changes an angle in a direction of extension in a region exiting between the two elements to ensure a distance from a line adjacent to the at least one of the first line, the second line, the third line, and the fourth line.

5. The quantum device according to claim 1, wherein, for a third qubit and/or a third coupler that are blocked at least by a fourth coupler and/or a fourth qubit arranged in a vicinity of the third qubit and/or the third coupler, the first line and the second line coupled capacitively and inductively to the third qubit, respectively, and the third line and the fourth line coupled capacitively and inductively to the third coupler, respectively, are wired using a three-dimensional wiring, to a first terminal and a second terminal, and/or to a third terminal and a fourth terminal, disposed on the outer edge of the wiring layer, respectively.

6. The quantum device according to claim 1, wherein the wiring layer incudes:
a plurality of first terminals, each connected to a second end of each of the plurality of first lines, a first end of each first line connected to a capacitive-coupling port of each of the plurality of qubits;
a plurality of second terminals, each connected to a second end of each of the plurality of second lines, a first end of each second line connected to an inductive-coupling port of each of the plurality of qubits;
a plurality of third terminals, each connected to a second end of each of the plurality of third lines, a first end of each third line connected to a capacitive-coupling port of each of the plurality of couplers; and
a plurality of fourth terminals, each connected to a second end of each of the plurality of fourth lines, a first end of each fourth line connected to an inductive-coupling port of each of the plurality of couplers,
wherein an arrangement pattern of three adjacent terminals among the first to fourth terminals includes:
a first arrangement pattern in which one of the second and fourth terminals is placed between two terminals selected from among the first and third terminals, and/or
a second arrangement pattern in which two terminals selected from among the second and fourth terminals are placed on both sides of one of the first and third terminals.

7. The quantum device according to claim 1, comprising
a chip that includes:
first and second rows of terminals arranged along opposing first edge and second edge of the chip, each row including a first terminal, a second terminal, a third terminal, and a fourth terminal that are connected to the first line, the second line, the third line and the fourth line, respectively, and
between the first and second rows of terminals, a network circuit including at least one unit structure including four qubits and one coupler with at least one qubit of the unit structure shared by at least one other unit structure,
the chip configured to be scaled-out in one direction parallel to the first edge and the second edge.

8. The quantum device according to claim 7, wherein the quantum chip includes
two or more coupling ports connected to a wiring layer of a wiring chip disposed opposing the quantum chip with first bumps, and through wiring routed on the wiring layer of the wiring chip, connected to the wiring layer of the quantum chip from the wiring layer of the wiring chip with second bumps to connect to at least one of the first terminal, the second terminal, the third terminal, and the fourth terminal of the first edge and the second edge, the coupling port being one of a plurality of coupling ports of the first line and the second line capacitively and inductively coupled to the qubit respectively, and the third line and the fourth line capacitively and inductively coupled to the coupler respectively, the coupler and the qubit included in the unit structure, arranged inner side of other unit structures disposed facing the first edge and the second edge, respectively.

9. The quantum device according to claim 1, comprising:
a plurality of a unit structure, each including four qubits and one coupler, wherein a quantum annealing machine is configured to have at least one qubit among the four qubits included one of the unit structures is shared by one or a plurality of other unit structures.

10. The quantum device according to claim 1, wherein the coupler comprises
opposing first and second electrodes; and
a second superconducting quantum interference device connected between the first and second electrodes, the second superconducting quantum interference device including at least two Josephson junctions in a loop,
wherein the third line is capacitively coupled to one of the opposing electrodes of the coupler, and
a direct current is supplied to the fourth line inductively coupled to one of the opposing electrodes of the coupler to bias the second superconducting quantum interference device with a direct current magnetic flux.

11. The quantum device according to claim 1, wherein the qubit comprises
a resonator including a first superconducting quantum interference device that includes at least two Josephson junctions in a loop,
wherein a direct current bias signal and a microwave signal are supplied to the second line, the direct current flowing through the second line generating a direct magnetic flux bias penetrating through the first superconducting quantum interference device, the microwave signal flowing through to the second line generating an alternating magnetic flux penetrating through the first superconducting quantum interference device to cause the resonator to perform parametric oscillation.

12. A quantum device comprising:
a substrate; and
a wiring layer formed on the substrate, wherein the wiring layer incudes:
a plurality of qubits;
a plurality of couplers, each connected to four of the plurality of qubits;
a plurality of first lines, each capacitively coupled to each qubit;
a plurality of second lines, each inductively coupled to each qubit;
a plurality of third lines, each capacitively coupled to each coupler;
a plurality of fourth lines, each inductively coupled to each coupler,
a plurality of first terminals, each connected to a second end of each of the plurality of first lines, a first end of each first line connected to a capacitive-coupling port of each of the plurality of qubits;
a plurality of second terminals, each connected to a second end of each of the plurality of second lines, a first end of each second line connected to an inductive-coupling port of each of the plurality of qubits;
a plurality of third terminals, each connected to a second end of each of the plurality of third lines, a first end of each third line connected to a capacitive-coupling port of each of the plurality of couplers; and
a plurality of fourth terminals, each connected to a second end of each of the plurality of fourth lines, a first end of each fourth line connected to an inductive-coupling port of each of the plurality of couplers,
wherein an arrangement pattern of three adjacent terminals among the first to fourth terminals includes:
a first arrangement pattern in which one of the second and fourth terminals is placed between two terminals selected from among the first and third terminals, and/or
a second arrangement pattern in which two terminals selected from among the second and fourth terminals are placed on both sides of one of the first and third terminals.
